(19) United States
(12) Patent Application Publication
(10) Pub. No.: US 2015/0381191 A1
(43) Pub. Date: Dec. 31, 2015

(54) VARIABLE DELAY COMPONENT RING OSCILLATOR WITH PHASE SHIFTING SELECT SWITCH

(71) Applicant: Texas Instruments Incorporated, Dallas, TX (US)

(72) Inventors: Michael A. Wu, Audubon, PA (US); Sudipto Chakraborty, Richardson, TX (US)

(21) Appl. No.: 14/318,228

(22) Filed: Jun. 27, 2014

(51) Int. Cl. H03L 7/099; H03L 7/08

(52) U.S. Cl. CPC H03L 7/0992; H03L 7/0802

(57) ABSTRACT

A circuit includes a ring oscillator component and a phase selecting component. The ring oscillator component outputs a clock signal having a clock frequency, f_{CLK}, and has a number n of delay components connected in series. The phase selecting component outputs a feedback clock signal, and has a switching component. The switching component can be in a first state and a second state, and can switch from the first state to the second state. The switching component outputs, in the first state, an output of a first delay component such that a signal output from the first delay component is the feedback clock signal having a first phase. The switching component outputs, in the second state, an output of a second delay component such that a signal output from the second delay component is the feedback clock signal having a second phase.

### BACKGROUND

The present invention generally relates to fractional-N division for Voltage Controlled Oscillator (VCO) and Phase Locked Loop (PLL) applications.

Fractional-N division is widely used in modem communication systems to synthesize frequencies that are fractional multiples of the reference frequency. Fractional-N division is conventionally realized by cascading multiple dividers from an oscillator switched by a high speed delta-sigma converter. In a conventional fractional-N or delta-sigma PLL, the clock output would be sent to a divider and then to the phase detector. In many applications the clock frequency needs to be controlled in small increments, in which case the feedback divider ratio can be quite substantial. One conventional solution uses counters or cascaded frequency dividers to implement a large division ratio between the VCO and the phase/frequency detector PFD. Another conventional solution may use pre-dividers implemented by a cascade of divide-by-two blocks with large division ratios obtained using phase multiplexing of individual I/Q phases.

FIG. 1 is a block diagram showing a conventional PLL 100.

As shown in the figure, PLL 100 includes a F_{REF} source 102, a pre-divider 106, a phase frequency detector (PFD) 110, a charge pump 113, a loop filter 114, a VCO 120 and a divider 124.

Far source 102 is operable to provide a reference clock signal 104 to pre-divider 106. Pre-divider 106 is operable to provide a PFD input 108 to PFD 110. PFD 110 is arranged to provide an error output signal 112 to the charge pump 113. Charge pump 113 is arranged to provide a modified voltage signal, based on error output signal 112 to loop filter 114. Loop filter 114 is arranged to provide a VCO input signal 116 to VCO 120. VCO 120 is operable to provide a VCO clock output 122 to divider 124. Divider 124 is operable to provide a feedback clock signal 126 to PFD 110.

Pre-divider 106 is operable to pre-divide the frequency of reference clock signal 104 by factor M, wherein M is an integer greater than or equal to one. Loop filter 114 is operable to filter error output 112 to provide VCO input signal 116. PFD 110 is operable to generate error output signal 112 representing the difference between the phases of PFD input 108 and feedback clock signal 126. Divider 124 is operable to divide the frequency of VCO clock output 122 by factor N to generate feedback clock signal 126, wherein N is an integer greater than or equal to one.

Generally, for a PLL of the same type as PLL 100, the VCO output frequency is the reference frequency of the input signal multiplied by the ratio of the feedback divider (N) to the pre-divider (M). So for PLL 100, the frequency of VCO clock output 122 is the frequency of reference clock signal 104 multiplied by N/M. This is achieved by generating a pre-scaled reference input frequency at PFD input 108 to PFD 110 from reference frequency signal 104 and pre-divider 106, then providing feedback clock signal 126 to PFD 110 via a negative feedback loop using feedback divider 124. Phases of feedback clock signal 126 and PFD input 108 are then compared by PFD 110. This generates error output signal 112 at the output of PFD 110. Error output signal 112 represents the phase difference seen at the inputs of PFD 110. Error output signal 112, filtered by loop filter 114, produces a voltage, VCO input signal 116, which is then used to make adjustments to the frequency generated by VCO 120 at output 122.

It should be noted from FIG. 1 that a circuit portion 118 includes VCO 120 and feedback divider 124 and that these are separate circuit blocks. This means that each requires supplied power and area for implementation. Furthermore, feedback divider and pre-divider power and circuit area requirements can be very large when, in order to realize small adjustment increments of the clock signal, the division ratios are required to be large.

What is needed is a method to achieve small adjustment increments of THE CLOCK SIGNAL using fewer circuit blocks and less circuitry in order to realize substantial power, circuit area and cost savings over the conventional methods.

### BRIEF SUMMARY

The present invention provides a unique system and method for the implementation of fractional-N division in VCO and PLL applications which, even for small clock adjustment increments, realizes considerable savings in supply power, circuit area and implementation cost over conventional methods.

An aspect of the present invention is drawn to a circuit including a ring oscillator component and a phase selecting component. The ring oscillator component outputs a clock signal having a clock frequency, f_{CLK}, and has a number n of delay components connected in series where the last stage output is fed back to the input of the first stage. The phase selecting component outputs a feedback clock signal, and has a switching component. The switching component can be in a first state or a second state, and can switch from the first state to the second state. The switching component outputs, in the first state, an output of a first delay component such that a signal output from the first delay component is the feedback clock signal having a first phase. In the second state, the switching component outputs a second delay component such that a signal output from said second delay component is the feedback clock signal having a second phase.

Additional advantages and novel features of the invention are set forth in part in the description which follows, and in part will become apparent to those skilled in the art upon examination of the following or may be learned by practice of the invention. The advantages of the invention may be realized and attained by means of the instrumentalities and combinations particularly pointed out in the appended claims.

### BRIEF SUMMARY OF THE DRAWINGS

The accompanying drawings, which are incorporated in and form a part of the specification, illustrate exemplary embodiments of the present invention and, together with the description, serve to explain the principles of the invention. In the drawings:

FIG. 1 shows a conventional PLL implementation;

FIG. 2 shows a simplified block diagram of the present invention:

FIG. 3 shows a ring oscillator component and a bus incorporating aspects of the present invention;

FIG. 4 is a block diagram showing an embodiment of a fractional divider operating in accordance with aspects of the present invention;

FIG. 5 is a timing diagram showing the behavior over time of the fractional divider of FIG. 4; and

FIG. 6 is a block diagram showing a second embodiment of a fractional divider operating in accordance with aspects of the present invention and incorporating adjustable delay components.

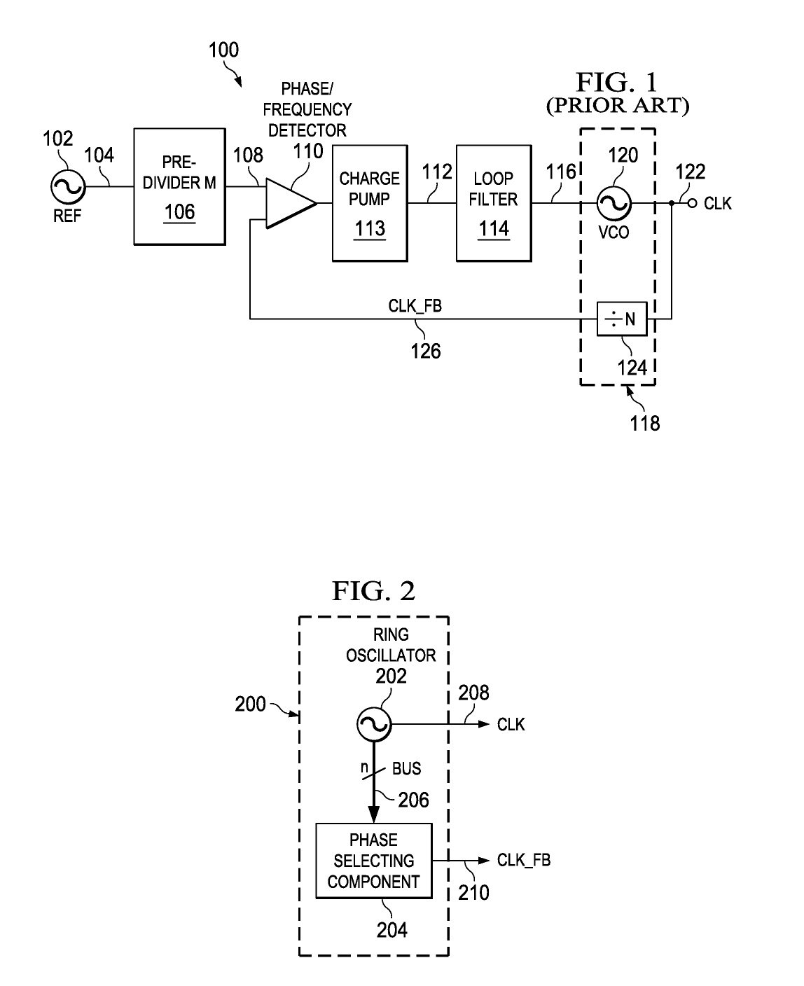

### DETAILED DESCRIPTION

Aspects of the present invention are drawn to a fractional divider for VCO and PLL applications, especially those requiring small incremental adjustments to frequency.

A first aspect of the present invention is drawn to the use of a conventional voltage-controlled ring oscillator to generate not only the main system clock, but also to derive fractional frequencies to the main clock. Use of the ring oscillator in this additional role, accomplishes significant savings in circuit complexity, space and cost.

A second aspect of the invention is drawn to the use of a phase selecting component that includes a switching component to select, in real-time, one of multiple selectable clocks to generate a divided feedback clock signal, such selectable clocks being derived from the main clock, differing from the main clock only by leading edge delay and therefore phase.

A third aspect of the invention is drawn to the use of a controlling component, to control the switching functions of the switching component. The switching controlling component, being configurable, can provide the switching necessary to realize a plurality of fractional division possibilities, limited only by the number of ring stages in the ring oscillator and the ring stage delays.

A fourth aspect of the invention is drawn to the use of variable-delay components in the ring generator and a delay controlling component to control their delay on a component by component basis. This aspect provides considerable additional flexibility in supporting the range of incremental frequency changes possible from the invention.

Aspects of the present invention will now be further described with reference to FIG. 2 through FIG. 6.

FIG. 2 is a high level block diagram showing fractional divider 200 in accordance with aspects of the present invention.

As shown in the figure, fractional divider 200 includes a ring oscillator component 202, a phase selecting component 204 and a bus 206.

As shown in the figure, ring oscillator component 202 is arranged to be connected to phase selecting component 204 via bus 206.

Ring oscillator component 202 is operable to generate a clock signal 208. Ring oscillator component 202 is additionally operable to provide an external interface, i.e., bus 206. Phase selecting component 204 is operable to produce a feedback clock signal 210.

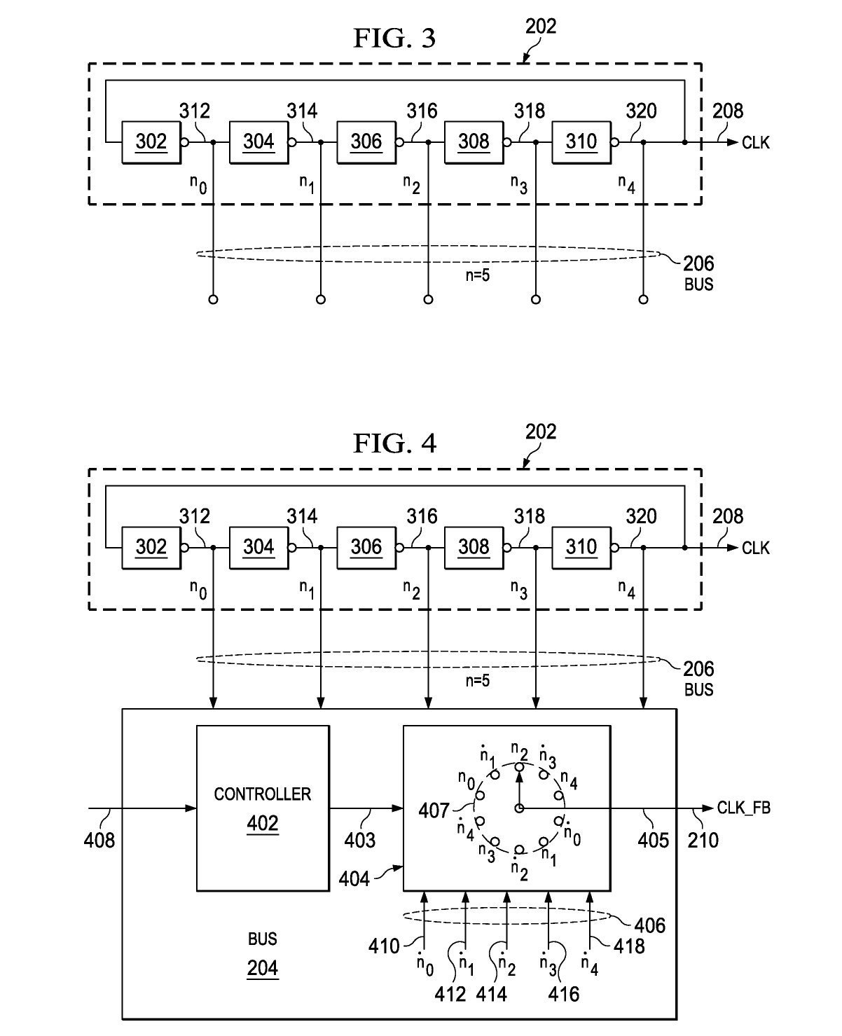

It should be noted that the provision of bus 206 by ring oscillator component 202 is a unique aspect of the present invention. This is further described using FIG. 3. Phase selecting component 204 uses the signals appearing on bus 206 to generate feedback clock signal 210. This will be further explained using FIG. 3 and FIG. 4.

FIG. 3 shows system 300 which illustrates ring oscillator component 202 and bus 206 of FIG. 2 in more detail.

As shown in FIG. 3, system 300 includes ring oscillator component 202 and bus 206. Ring oscillator 202 includes delay component 302, delay component 304, delay component 306, delay component 308 and delay component 310. Bus 206 includes a tap 312, a tap 314, a tap 316, a tap 318 and a tap 320.

Delay component 304 is arranged between delay component 302 and delay component 306. Delay component 306 is arranged between delay component 304 and delay component 308. Delay component 308 is arranged between delay component 306 and delay component 310. Delay component 310 is arranged between delay component 308 and delay component 302. Delay component 310 is also arranged to provide clock signal 208. Tap 312 is arranged to connect between delay component 302 and delay component 304, tap 314 is arranged to connect between delay component 304 and delay component 306, tap 316 is arranged to connect between delay component 306 and delay component 308, tap 318 is arranged to connect between delay component 308 and delay component 310 and a tap 320 is arranged to connect between delay component 310 and delay component 302.

Delay component 302 is operable to provide an output 312 to delay component 304. Delay component 304 is operable to provide an output 314 to delay component 306. Delay component 306 is operable to provide an output 316 to delay component 308. Delay component 308 is operable to provide an output 318 to delay component 310. Delay component 310 is operable to output clock signal 208. Delay component 302 is additionally arranged to receive clock signal 208 from delay component 310.

In the figure, delay component 302, delay component 304, delay component 306, delay component 308 and delay component 310 together with the feedback path between delay component 310 and delay component 302 form a conventional ring oscillator with five stages—each delay component being a stage, respectively. It should be noted that in order for the ring oscillator to operate, the delay components must also provide a signal inversion function for odd number of stages. In accordance with aspects of the present invention, bus 206 taps off the signals appearing at taps 312 through 320 respectively. In ring oscillator component 202, each of five delay components 302 through 310 exhibits the same delay, Δ. Thus, the delay between any successive pair of signals on taps 312 through 320 is also Δ and, due to Δ, there is a phase shift between any successive pair of taps with the phase increasingly lagging behind clock signal 208 from tap 312 through tap 320.

One example of a conventional ring oscillator includes an odd number of NOT gates whose inverting output oscillates between two voltage levels, representing true and false. The NOT gates, or delay components, are attached in a chain; the output of the last delay component is fed back into the first. The oscillator period for a conventional ring oscillator is equal to twice the sum of the individual delays of all stages. It should be noted that this describes an example embodiment of system 300 where the delay components are simple inverters.

Phase selecting component 204 is discussed in more detail using a block diagram.

FIG. 4 is a block diagram 400 showing phase selecting component 204 of FIG. 2 in more detail including its interconnection to ring oscillator component 202.

As shown in the figure, block diagram 400 includes ring oscillator 202, bus 206, phase selecting component 204 and a line 405. Ring oscillator 202 and bus 206 include components which were previously described for FIG. 3 and for brevity the description will not be repeated in this section. Phase selecting component 204 includes a switch controlling component 402, a switching component 404 and a bus 406. Bus 406 includes tap 410, tap 412, tap 414, tap 416 and tap 418.

Bus 206 is arranged to connect to switching component 404. Bus 406 is arranged to connect to switching component 404. Switch controlling component 402 is arranged to output a control signal 403 to switching component 404. Switching component 404 is arranged to connect to clock output 210. Controlling component input 408 is arranged to connect to switch controlling component 402.

Ring oscillator 202 is operable to generate clock signal 208. Bus 406 is operable to produce an inverted version of bus 206 such that tap 410 is the inversion of tap 312, tap 412 is the inversion of tap 314, tap 414 is the inversion of tap 316, tap 416 is the inversion of tap 318 and tap 418 is the inversion of tap 320. Switch controlling component 402 is operable to generate control signal 403 to control the switching actions of switching component 404. Switching component 404 is operable to switch one of a plurality of signals on bus 206 to line 405.

In operation, switching component 404, under the control of switch controlling component 402, switches the plurality of signals appearing on bus 206 and on bus 406 through to line 405 in order to produce feedback clock signal 210 having a specific frequency. In order to produce different specific frequencies of clock signal 210, switching component 404 moves over time through a series of states during which it either switches to another tap or does not switch to another tap. Switching to another tap causes a change in phase of feedback clock 210, either forward or backward in phase depending on the direction of movement. The magnitude of the change in phase depends on the number of taps moved during each switch action. Frequency changes occur because changes in phase introduce a lengthening or shortening of the wave period of feedback clock 210. This operation is further explained later using a timing diagram.

In this embodiment, switch controlling component 402 uses information appearing on controlling component input 408 for a plurality of functions. For example, controlling component input 408 may be a selection signal, wherein switch controlling component 402 may be a selector component that receives the selection signal and selects a future state of switching component 404 based on the selection signal. These are non-limiting, but may include remote configuration of switch controlling component 402, remote control, programming, or any signal required for real-time operation. In another embodiment, controlling component input 408 may not be needed or provided, that is, switch controlling component 402 functions self-sufficiently.

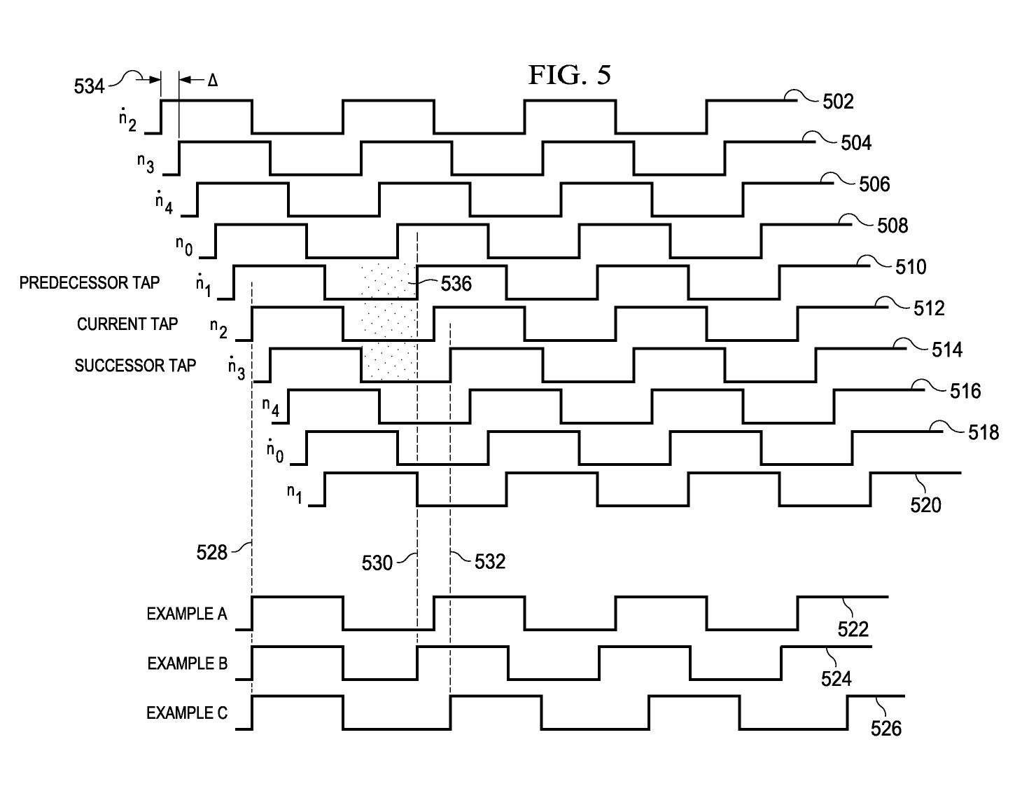

The operation of fractional divider 200 can be further explained with additional reference to FIG. 5.

FIG. 5 shows timing diagram 500, which illustrates the operational timing of fractional divider 200 for various example scenarios.

In FIG. 5, timing diagram 500 includes a waveform 502, a waveform 504, a waveform 506, a waveform 508, a waveform 510, a waveform 512, a waveform 514, a waveform 516, a waveform 518, a waveform 520, a feedback clock waveform 522, a feedback clock waveform 524, a feedback clock waveform 526, a dotted line 528, a dotted line 530, a dotted line 532, a tap delay 534 and a switching region 536.

Waveforms 508, 520, 512, 504, and 516, respectively, represent the oscillator tap outputs of tap 312, tap 314, tap 316, tap 318 and tap 320, respectively, of FIG. 3, these appearing on bus 206. Waveforms 518, 510, 502, 514, and 506, respectively, represent the inverted outputs of tap 312, tap 314, tap 316, tap 318 and tap 320, respectively, of FIG. 3, that is tap 410, tap 412, tap 414, tap 416 and tap 418, respectively, of FIG. 4 these appearing on bus 406.

Tap delay 534, Δ, represents the delay between each stage of ring oscillator 202 of FIG. 2. Switching region 536 represents the region of time during which switching of switching component 404 is allowed to occur for the operational examples following.

For the purposes of discussion, presume that at switching component 404, line 405 is switched through to tap 316 such that feedback clock 524 is waveform 512. Since tap 316 is the tap currently switched to by switching component 412, tap 316 is considered “the current tap”. For the purposes of discussion of operation, timing diagram 500 considers the case where the movement of switching component 404 is one tap at a time around a circle 407 of FIG. 4. Since on circle 407, tap 412 precedes tap 316, tap 412 is considered the predecessor tap. Similarly, since tap 416 succeeds tap 412 on circle 407, tap 416 is considered the successor tap.

Dotted line 528 indicates a point in time where waveform appearing on the current tap, waveform 512 is at a rising edge. Dotted line 528 also indicates when feedback clock waveform 522, feedback clock waveform 524 and feedback clock waveform 526 are aligned in time with the waveform on current tap, waveform 512. Dotted line 530 indicates the first rising edge of predecessor tap 510 occurring after dotted line 528. Dotted line 532 indicates the first rising edge of successor tap 514 occurring after dotted line 528.

It can be seen that clock signal 208, which is the clock generated by ring oscillator 202, is shown by waveform 516 of FIG. 5, since this is the signal appearing on tap 320. Given that waveform 512 represents the current feedback clock, that is feedback clock signal 210, it can be seen that the phase of feedback clock signal 210 is leading the phase of clock signal 208 by a time 2A, or could be considered lagging the phase of clock signal 208 by 3A, depending upon the direction travelled around the loop formed by the five delay components 302 through 310.

In operation, ring oscillator 202 produces waveforms 502 through 526 on bus 206 and bus 406 of FIG. 4. It can be seen from timing diagram 500 that for waveforms arranged in the order shown, any waveforms is the previous waveform delayed by one tap delay. A. Switching component 404 is able to remain on a tap (or inverted tap), or to switch from one tap to another.

It is important to note that if switching component 404 remains at any of the taps, feedback clock signal 210 will be the same frequency as clock signal 208 but with a phase shift due to the delay components between them. For example, given that clock signal 208 is at tap 320, if switching component remains at tap 316, which is lagging three delay components (delay component 302, delay component 304 and delay component 306) behind tap 320, there will be a three tap phase delay, i.e. a 3A lag, of feedback clock signal 210 behind clock signal 208. In the case illustrated by timing diagram 500, switching component 404 is pointed at the current tap, which is tap 316 producing current tap waveform 512. Example A (feedback clock 522), shows the case where switching component 404 remains at this tap, and feedback clock 522 also shows that feedback clock signal 210 is the same frequency as clock signal 208.

Changes in frequency can be achieved by moving switching component 404 to another tap from the current tap. As stated earlier, for the purposes of discussion of operation, timing diagram 500 examples consider the case where the movement of switching component 404 is one tap at a time. While switching could be done at any time, it is best done during switching region 536 since this will give the smoothest transition with the least jitter. Switching region 536 is between the falling edge of the successor tap and the next rising edge of the predecessor tap. For all switching examples described it is assumed that switching is always done during the appropriate switching region. Switching actions are controlled by switch controlling component 402.

An increase in frequency is realized by moving switching component 404 to the predecessor tap. This case is illustrated in FIG. 5 by Example B. Example B shows feedback clock waveform 524, which is feedback clock signal 210 as produced by switching from the current tap to the predecessor tap during switching region 536. It can be seen from feedback clock waveform 524 and dotted line 530 that after switching from the current tap, the next rising edge has become that of the earlier occurring predecessor tap. This has resulted in a shortening of the wavelength for that clock cycle (as compared to the case where switching component has not moved) and therefore an increase in frequency.

Example C shows the case where a decrease in frequency is achieved by moving switching component 404 from the current tap to the successor tap. It can be seen from feedback clock waveform 526 and dotted line 532 that after switching from the current tap, the next rising edge has become that of the later occurring successor tap. This has resulted in a lengthening of the wavelength of feedback clock 526, and therefore feedback clock signal 210, for that clock cycle (as compared to the case where switching component has not moved) and therefore a decrease in frequency.

Operation of fractional divider 200 has been described above using a single clock period, but in continuous operation, switching decisions are made every clock period by switch controlling component 402. Switch controlling component 402 not only ensures that switching is done at the appropriate time in the clock cycle, but it is able to apply any sequence of switching actions in order realize fractional frequency adjustments of feedback clock signal 210.

At the limits, switch controlling component 402 switches every clock cycle. For Example B, this is equivalent to moving the pointer of switching component 404 counter-clockwise one tap per clock cycle. Expanding the case described for Example B to switching every cycle, every clock cycle will be reduced by one tap delay and the maximum frequency for adjacent tap switching becomes:

fₘₐₓ=2n/(2n−1)*f_{CLK}, (1)

where n is the number of stages (tap delays) in the ring oscillator, and f_{CLK} is the current frequency of the clock signal.

Similarly, Example C is equivalent to moving the pointer of switching component 404 clockwise one tap per clock cycle. Expanding the case described by Example C, the minimum frequency for adjacent tap switching becomes:

fmin=2n/(2n÷1)*f_{CLK} (2)

In order to realize fractional frequency changes between fₘₐₓ and fₘᵢₙ, switching component 404 can remain on the current tap for a number of cycles instead of switching by one tap every cycle. For example, if over ten cycles, switching component 404 moves clockwise one tap for all ten cycles, the wave period of feedback clock signal 210 is increased by 10Δ which yields a particular frequency. If, however, over ten cycles, switching component moves clockwise for nine of the cycles but remains in place for one of the cycles, the wave period of feedback clock signal 210 is increased by only 9Δ which yields a higher frequency.

It is also possible to switch between two non-adjacent taps. For example, switching component 404 can switch by two taps from the tap 316 (waveform 512) to tap 312 (waveform 508) or to tap 320 (waveform 516). In such cases, and assuming that the same number of taps is skipped for each move, the maximum frequency becomes:

fₘₐₓ=2n/(2n−N)*f_{CLK} (3)

where N is an integer greater than or equal to one and is the number of taps moved each cycle. The minimum frequency becomes:

fₘᵢₙ=2n/(2n+N)*f_{CLK} (4)

The above discussion describes switching between non-adjacent taps. If operated in this mode, switching region 536 narrows. Switching region 536 is defined as the period of time during which all of the possible taps which can be switched to have the same value, which in this example is zero.

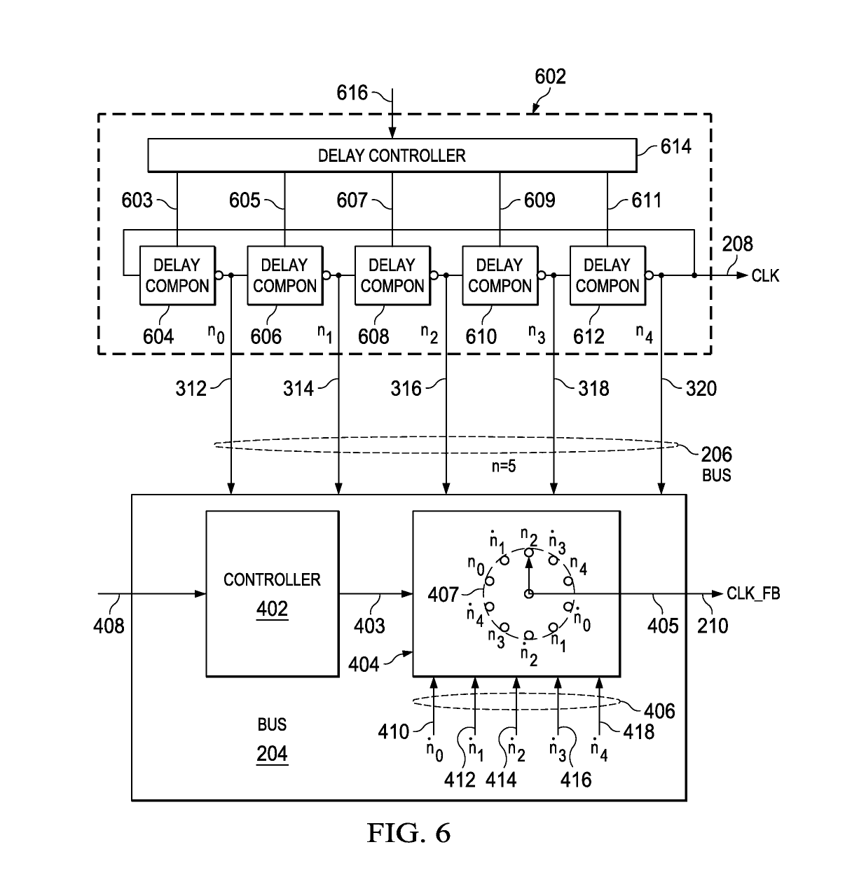

The descriptions above have illustrated in detail the first three major aspects of the present invention. It has been shown that the VCO, a conventional component already existing in a conventional system, can be leveraged to provide to provide additional signals on a bus, the phases and phase relationships of which are used in a unique manner to derive fractional frequencies to the primary clock, including those related to the primary clock by small increments. It has also been shown how a switching component controlled by a switching controlling component can select between the phases in order to derive the desired frequency. Next, the fourth major aspect of the present invention will be described using FIG. 6.

FIG. 6 is an embodiment in accordance with aspects of the present invention representing the fractional divider of FIG. 4 but with variable delay components for the ring oscillator stages.

The majority of the components of FIG. 6 have already been listed and described for FIG. 4.

For FIG. 6, ring oscillator 602 replaces ring oscillator 202 of FIG. 4. All other components of FIG. 6 are the same as for FIG. 4 and, in the interests of brevity, these will not be described again. Ring oscillator 602 includes a variable delay component 604, a variable delay component 606, a variable delay component 608, a variable delay component 610, a variable delay component 612, a delay controlling component 614 a controller input 616, a line 603, a line 605, a line 607, a line 609 and a line 611.

Variable delay component 606 is arranged between variable delay component 604 and variable delay component 608. Variable delay component 608 is arranged between variable delay component 606 and variable delay component 610. Variable delay component 610 is arranged between variable delay component 608 and variable delay component 612. Variable delay component 612 is arranged between variable delay component 610 and variable delay component 604. Variable delay component 612 is also arranged to provide clock signal 208. Delay controlling component 614 is arranged to connect to of variable delay component 604 via line 603, variable delay component 606 via line 605, variable delay component 608 via line 607, variable delay component 610 via line 609 and variable delay component 612 via line 611. Tap 312 is arranged to connect between variable delay component 604 and variable delay component 606, tap 314 is arranged to connect between variable delay component 606 and variable delay component 608, tap 316 is arranged to connect between variable delay component 608 and variable delay component 610, tap 318 is arranged to connect between variable delay component 610 and variable delay component 612 and a tap 320 is arranged to connect between variable delay component 612 and variable delay component 604.

Variable delay component 604, variable delay component 606, variable delay component 608, variable delay component 610 and variable delay component 612 are operable as a five stage ring oscillator and as such also provide an inversion function. Delay controlling component 614 is operable to separately control the delay of each of variable delay component 604, variable delay component 606, variable delay component 608, variable delay component 610 and variable delay component 612.

In this embodiment, delay controlling component 614 can use information appearing on controller input 616 for a plurality of functions. These are non-limiting, but may include remote configuration of delay controlling component 614, remote control, programming, or any signal required for real-time operation. In another embodiment, controller input 616 may not be needed or provided, that is, delay controlling component 614 functions self-sufficiently.

In this embodiment, the delay components of the ring oscillator are adjustable for delay value. The delay components can be adjusted all to the same delay or to different delays under control of delay controlling component 614.

In a first example operation, delay controlling component 614 sets the delay of all variable delay components to the same value, e.g. A. For this example, the operation of the fractional divider of FIG. 6 will be the same as for the fractional divider of FIG. 4, which has already been described.

In a second example operation, delay controlling component 614 sets the delay of the variable delay components to a plurality of values, e.g. Δ₀, Δ₁, Δ₂, Δ₃ Δ₄ for a five stage ring oscillator. The wave period of a ring oscillator is the sum of all the delay stages, so the wave period of this ring oscillator is:

λ=Δ₀+Δ₁+Δ₂+Δ₃+Δ₄ (5)

The frequency of ring oscillator 602 is thus set. That is, the frequency of clock signal 208 is proportional to the inverse of the sum of the delay stages. The frequency of feedback clock 210 is controlled by the sequence of selection of the taps. However, since there is a plurality of delay values, switch controlling component 402 can now choose future switch events and states based on these individual delay values to achieve the desired frequency. In this example operation, therefore, the range of possible incremental values of feedback clock signal 210 is enhanced since it is no longer limited by a single value of A.

The example ring oscillator discussed above provides 5 stages of delay. It should be noted that this is a non-limiting example, wherein any number of stages, or an n-stage ring oscillator, may be used in accordance with aspects of the present invention.

Use of the components, methods and techniques described results in significant savings in circuitry and power over conventional fractional-N division techniques, especially where frequency increments need to be small since conventional techniques require large multi-stage divider circuits. The savings can translate into smaller devices utilizing less power for implementation and thus distinct cost advantages over conventional techniques. In addition, in conjunction with the other aspects of the present invention just described, the use of variable delay stages in the ring oscillator is a significant enhancement to the prior art, allowing support of a much wider range of incremental frequency changes to the clock signal in order to produce the desired feedback clock frequency. The foregoing description of various preferred embodiments of the invention have been presented for purposes of illustration and description. It is not intended to be exhaustive or to limit the invention to the precise forms disclosed, and obviously many modifications and variations are possible in light of the above teaching. The example embodiments, as described above, were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

1. A circuit comprising:
a ring oscillator having an output a clock signal having a clock frequency, f_{CLK}, the ring oscillator having a number n of variable delay components connected in series, each variable delay component having an associated input and an associated output, and having a variable delay control input; and
a phase selecting component having a feedback clock signal output based on a divider ratio of the clock signal, the phase selecting component including a switching component,
the switching component having a first state, a second state, and can be switched from the first state to the second state,
in the first state, the switching component outputting an output of a first variable delay component such that a signal output from the first variable delay component is a feedback clock signal having a first phase,
in the second state, the switching component outputting an output of a second variable delay component such that a signal output from the second variable delay component is a feedback clock signal having a second phase, and
the first phase is different from the second phase.

2. The circuit of claim 1, including a switch controlling component operable to switch said switching component from the first state to the second state.

3. The circuit of claim 2, in which the first phase is less than the second phase.

4. The circuit of claim 3,
in which the feedback clock signal has a maximum frequency, fₘₐₓ, as fₘₐₓ=2n/(2n−N)*f_{CLK}, and
in which N is an integer greater than or equal to one.

5. The circuit of claim 4, in which the feedback clock signal has a minimum frequency, fₘᵢₙ, as fₘᵢₙ=2n/(2n+N)*f_{CLK}.

6. The circuit of claim 5, including:
a variable delay controlling component operable to generate a variable delay control signal, and
one of the variable delay components is operable to change its variable delay amount based on the variable delay control signal.

7. The circuit of claim 6, wherein the switch controlling component includes a selector component operable to receive a selection signal and to select a future state of the switching component based on the selection signal.

8. The circuit of claim 7,
in which the switching component is operable to be in n states,
in which the selector component is operable to select x future states of the switching component, and
in which x<n.

9. The circuit of claim 1, in which the first phase is less than the second phase.

10. The circuit of claim 9,
in which the feedback clock signal has a maximum frequency, fₘₐₓ, as fₘₐₓ=2n/(2n−N)*f_{CLK}, and
in which N is an integer greater than or equal to one.

11. The circuit of claim 10, in which the feedback clock signal has a minimum frequency, fₘᵢₙ, as fₘᵢₙ=2n/(2n+N)*f_{CLK}.

12. The circuit of claim 11, including:
a variable delay controlling component operable to generate a variable delay control signal, and
one of the variable delay components is operable to change its variable delay amount based on the variable delay control signal.

13. The circuit of claim 12,
in which the switching component is operable to be in n states,
in which the selector component is operable to select x future states of the switching component, and
the x<n.

14. The circuit of claim 1,
in which the feedback clock signal has a maximum frequency, fₘₐₓ, as fₘₐₓ=2n/(2n+N)*f_{CLK}, and
in which N is an integer greater than or equal to one.

15. The circuit of claim 14, in which the feedback clock signal has a minimum frequency, fₘᵢₙ, as fₘᵢₙ=2n/(2n+N)*f_{CLK}.

16. The circuit of claim 15, including:
a variable delay controlling component operable to generate a variable delay control signal, and
one of the variable delay components is operable to change its variable delay amount based on the variable delay control signal.

17. The circuit of claim 16,
in which the switching component is operable to be in n states,
in which the selector component is operable to select x future states of said switching component, and
in which x<n.

18. The circuit of claim 1,
in which the switching component is operable to be in n states,
in which the selector component is operable to select x future states of the switching component, and
in which x<n.

19. The circuit of claim 1 including a variable delay controlling component having a variable delay control signal output coupled to the variable delay control input.

20. The circuit of claim 1 including a variable delay controlling component having a variable delay control signal output coupled to each of the variable delay control inputs.
